(19) United States
(12) Patent Application Publication
(10) Pub. No.: US 2006/0180927 A1
(43) Pub. Date: Aug. 17, 2006

(54) Contact structure and method for manufacturing the same

(76) Inventors: Daisuke Takai, San Jose, CA (US); Masami Aihara, San Jose, CA (US); Koichi Takahashi, Miyagi (JP)

Correspondence Address: BRINKS HOFER GILSON & LIONE, P.O. BOX 10395, CHICAGO, IL, 60610, US

(21) Appl. No.: 11/057,696

(22) Filed: Feb. 14, 2005

(51) Int. Cl. H01L 23/48

(52) U.S. Cl. 257/734

(57) ABSTRACT

A contact structure includes contact members having leg portions which are deflected using internal stresses. Since the internal stress is used, the leg portions of the contact members are easily and reliably deflected even when the size of the contact members is reduced in accordance with the size reduction of an electronic component. Since the leg portions are elastically deformed and function as elastic contacts, a strain caused by a difference in coefficient of thermal expansion between the electronic component and the substrate can be absorbed by the contact members. In addition, since a plurality of elastic contacts are provided, even if there is a displacement between the electronic component and the substrate, an electrical connection between the electronic component and the substrate is reliably obtained.

### BACKGROUND OF THE INVENTION

1. Field of the Invention

The present invention relates to contact structures provided between electronic components, such as ICs, and substrates, and more specifically to a contact structure which provides a good electrical connection between an electronic component and a substrate even when the size of the electronic component is reduced and a manufacturing method for the contact structure.

2. Description of the Related Art

When there is a large difference in coefficient of thermal expansion between a substrate and an electronic component, such as an IC, a structure in which a spring component or the like is provided at a terminal of the electronic component may be applied to absorb a strain caused by the difference in coefficient of thermal expansion.

When the size of the electronic component is reduced to a hyperfine level, the size of the spring component must also be greatly reduced. In this case, it becomes difficult to form a three-dimensional shape of the spring component as the size of the spring component is reduced. In addition, the spring component must exert a certain elastic force to adequately absorb the strain caused by the difference in coefficient of thermal expansion.

On the other hand, when the size of the electronic component is reduced to a hyperfine level, the electronic component and the substrate must be positioned relative to each other with high precision.

Japanese Patent No. 3099066 discloses an invention related to methods for manufacturing thin-film structures, and a thin-film structure manufactured by bending a thin film using an internal stress is described in claim 5 and the explanations of FIGS. 17 to 22.

However, Japanese Patent No. 3099066 neither discloses nor suggests the use of the thin-film structure as a contact structure between an electronic component, such as an IC, and a substrate. Although Japanese Patent No. 3366405 discloses a method for manufacturing a hyperfine structure made of metal, it does not describe the use of the hyperfine structure as a contact structure. In addition, the hyperfine structure is not formed in a three-dimensional shape like a spring.

As the size of the electronic component is reduced, it becomes more difficult to control the position where the spring component is disposed between the electronic component and the substrate with high precision. In addition, a displacement easily occurs between the substrate and the electronic component as the size is reduced, and it becomes difficult to provide a reliable electrical connection between the electronic component and the substrate using the spring component.

### SUMMARY OF THE INVENTION

In order to solve the above-described problems, the present invention is directed to contact structures attached to electronic components, such as ICs, and more specifically to a contact structure which provides a good electrical connection between an electronic component and a substrate even when the size of the electronic component is reduced and a manufacturing method for the contact structure.

According to the present invention, a contact structure includes a plurality of laminated contact members, each contact member having a fixed portion and a leg portion extending from the fixed portion. The contact members are bonded to each other at the fixed portions and at least one of the leg portions is deflected in a direction perpendicular to a lamination direction of the contact members.

According to the present invention, the leg portions of the contact members can be adequately deflected and be used as elastic contacts even when the size of the electronic component or the like is reduced. In addition, according to the present invention, since the laminated leg portions function as elastic contacts, a strain caused by a difference in coefficient of thermal expansion between the electronic component and the substrate, which are electrically connected to each other with the contact structure, can be absorbed by the contact members. In addition, since a plurality of elastic contacts are provided, even if there is a displacement between the electronic component and the substrate, a reliable electrical connection is provided between the electronic component and the substrate.

Thus, according to the present invention, since a plurality of contact members are provided, the electronic component and the substrate are electrically connected to each other with a plurality of contacts. Therefore, the contact reliability can be increased compared to that of the known structure.

In addition, according to the present invention, sacrificial layers are preferably provided between the fixed portions. In such a case, the sacrificial layers are preferably made of a conductive material. Accordingly, the fixed portions of the contact members are reliably bonded to each other with the sacrificial layers. In addition, if the sacrificial layers are made of a conductive material, the electronic component and the substrate can be electrically connected to each other via the leg portions, the fixed portions, and the sacrificial layers. Thus, the electronic component and the substrate can be electrically connected to each other with a simple structure.

In addition, according to the present invention, the contact members are preferably formed by thin-film formation. Accordingly, the size of the contact structure can be reduced.

In addition, according to the present invention, all of the leg portions are preferably deflected in the same direction which is perpendicular to the lamination direction. In such a case, a plurality of elastic contacts are arranged so as to face, for example, a terminal of the electronic component, and therefore at least one of the elastic contacts easily comes into contact with the terminal of the electronic component. Therefore, the contact reliability is increased. In addition, according to the present invention, if all of the leg portions are deflected upward, the leg portions are preferably arranged from the bottom in the order of length, the shortest leg portion being positioned at the top. In such a case, the leg portions easily and reliably come into contact with the terminal of the electronic component, and accordingly the contact reliability is further increased.

According to the present invention, at least one of the leg portions may be deflected in a direction different from the direction in which the other leg portions are deflected. In such a case, preferably, the contact structure further includes a sheet member to which the fixed portions of the contact members are bonded and which has a through hole. In addition, the leg portion of at least one of the contact members is deflected away from the sheet member, and the leg portions of the other contact members are deflected toward the sheet member so as to extend through the through hole and protrude from a surface of the sheet member opposite to a surface on which the fixed portions are bonded. Accordingly, when, for example, the contact structure is provided between the substrate and the electronic component, both of the substrate and the electronic component can be reliably connected to the elastic contacts with a simple structure.

In addition, according to the present invention, a method for manufacturing a contact structure includes (a) a step of performing a film-formation process for laminating a sacrificial layer and a contact member a plurality of times to form a plurality of sacrificial layers and contact layers such that different internal stresses are applied between top and bottom sides of each contact member and (b) a step of removing the sacrificial layers in regions under leg portions of the contact members so that the leg portions are deflected by the internal stresses.

The method according to the present invention is characterized in that the film-formation process for laminating a sacrificial layer and a contact member is performed a plurality of times to form a plurality of sacrificial layers and contact members and different internal stresses are applied between top and bottom sides of each contact member in step (a), and in that the sacrificial layers are removed in regions under leg portions of the contact members so that the leg portions are deflected by the internal stresses in step (b).

By performing the above-described steps, the leg portions of the contact members are easily deflected even when the size of the contact members is reduced in accordance with the size reduction of the electronic component. Accordingly, an electrical connection between the electronic component and the substrate is easily and reliably provided by a plurality of elastic contacts.

According to the present invention, preferably, in step (a), the contact members are formed by sputter deposition and the internal stresses of the contact members are controlled by changing a vacuum gas pressure.

In addition, according to the present invention, preferably, a tensile stress and a compressive stress are applied to the bottom and top sides, respectively, of each of the contact members in step (a), so that the leg portions of all of the contact members are deflected upward in step (b). In such a case, at least before step (b) is performed, the shapes of the contact members are preferably adjusted such that the contact members are arranged from the bottom in the order of length of the leg portions, the shortest leg portion being positioned at the top.

In addition, according to the present invention, preferably, in step (a), a sheet material is laminated on a base and the film-formation process is performed a plurality of times such that a compressive stress and a tensile stress are applied to the bottom and top sides, respectively, of at least the lowermost contact member and a tensile stress and a compressive stress are applied to the bottom and top sides, respectively, of at least the uppermost contact member. In addition, preferably, a through hole is formed in the sheet member at least before step (b) is performed so that, in step (b), the leg portion of at least the lowermost contact member is deflected downward to protrude from a bottom surface of the sheet member through the through hole and the leg portion of at least the uppermost contact member is deflected upward. Accordingly, a simple contact structure is obtained in which both of the substrate and the electronic component can be reliably connected to the elastic contacts.

The present invention provides advantages in that the leg portions of the contact members can be adequately deflected and be used as elastic contacts even when the size of the electronic component or the like is reduced. In addition, according to the present invention, since the laminated leg portions function as elastic contacts, a strain caused by a difference in coefficient of thermal expansion between the electronic component and the substrate, which are electrically connected to each other with the contact structure, can be absorbed by the contact members. In addition, since a plurality of elastic contacts are provided, even if there is a displacement between the electronic component and the substrate, a reliable electrical connection is provided between the electronic component and the substrate.

Thus, according to the present invention, since a plurality of contact members are provided, the electronic component and the substrate are electrically connected to each other with a plurality of contacts. Therefore, the contact reliability can be increased compared to that of the known structure.

### BRIEF DESCRIPTION OF THE DRAWINGS

FIG. 1 is a partial sectional view showing a substrate, an electronic component, and contact structures according to a first embodiment of the present invention;

FIG. 2 is an enlarged sectional view showing a part of each contact structure shown in FIG. 1;

FIG. 3 is a partial sectional view showing a substrate, an electronic component, and contact structures according to a second embodiment of the present invention;

FIG. 4 is an enlarged sectional view showing a part of the contact structure shown in FIG. 3;

FIG. 5 is a partial sectional view showing contact structures according to a third embodiment of the present invention;

FIG. 6 is a process chart of a manufacturing method of each contact structure shown in FIG. 1, showing a partial sectional view of the contact structure being manufactured;

FIG. 7 is a partial sectional view showing the step performed after the step shown in FIG. 6;

FIG. 8 is a partial sectional view showing the step performed after the step shown in FIG. 7;

FIG. 9 is a partial sectional view showing the step performed after the step shown in FIG. 8;

FIG. 10 is a partial sectional view showing the step performed after the step shown in FIG. 9;

FIG. 11 is a partial sectional view of another manufacturing method (second manufacturing method) of each contact structure shown in FIG. 1.

FIG. 12 is a partial sectional view showing the step performed after the step shown in FIG. 11;

FIG. 13 is a partial sectional view showing the step performed after the step shown in FIG. 12;

FIG. 14 is a partial sectional view of a manufacturing method of the interposer shown in FIG. 3.

FIG. 15 is a partial sectional view showing the step performed after the step shown in FIG. 14; and

FIG. 16 is a partial sectional view showing the step performed after the step shown in FIG. 15.

### DESCRIPTION OF THE PREFERRED EMBODIMENTS

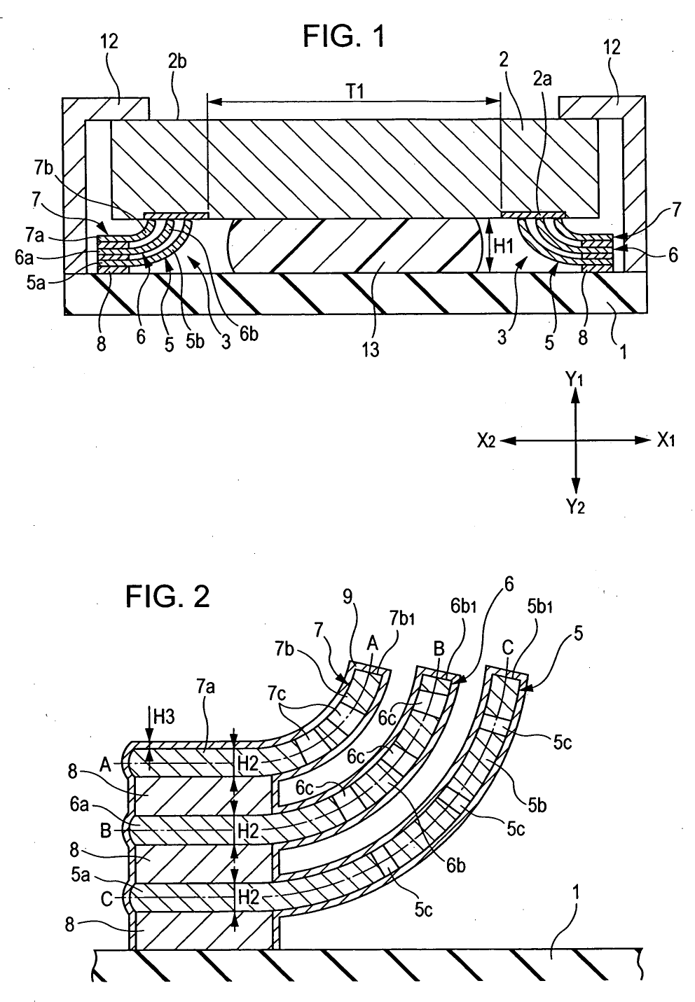

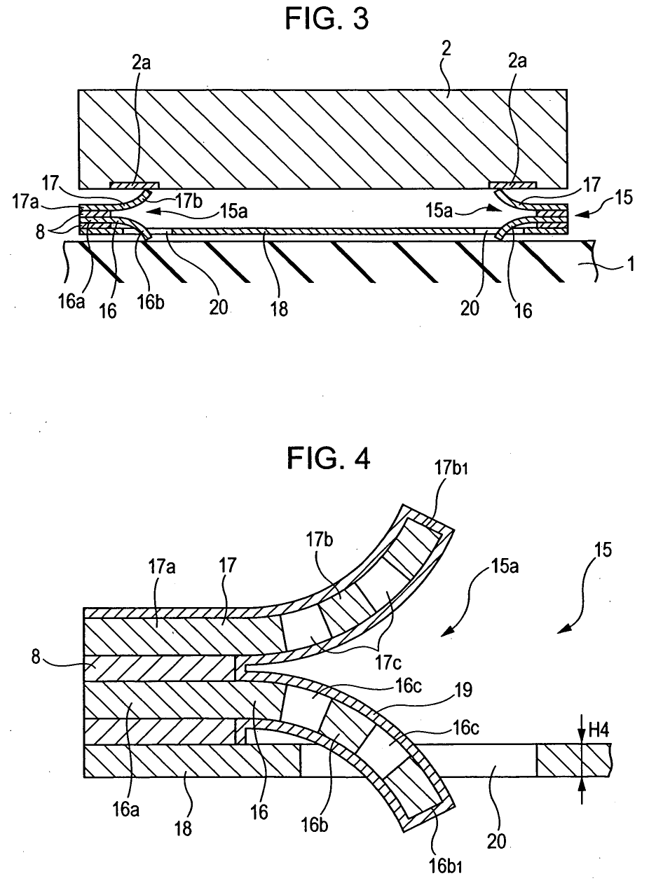

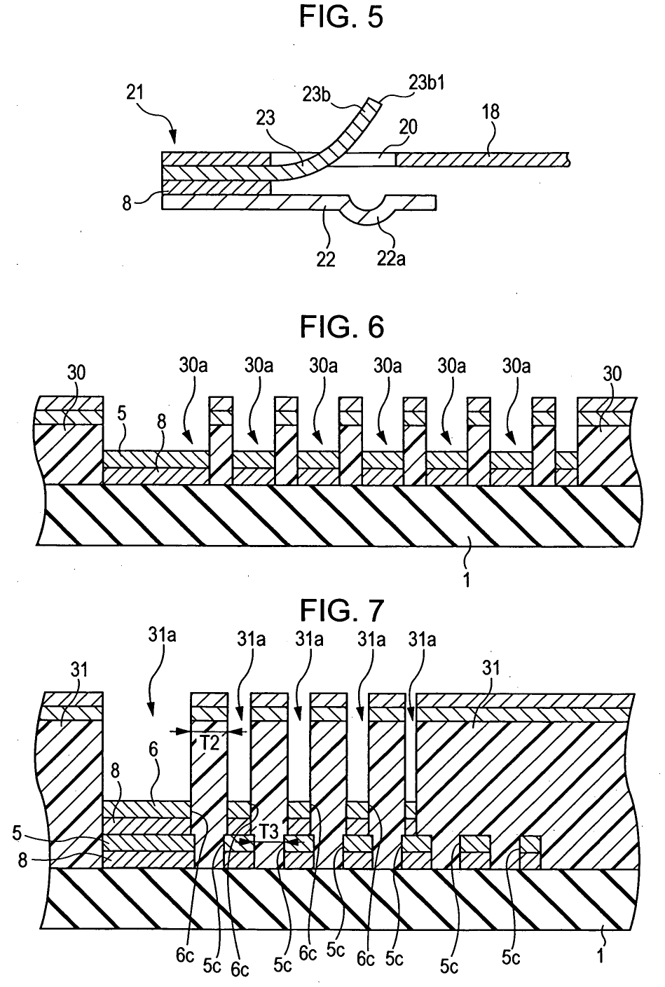

FIG. 1 is a partial sectional view showing a substrate, an electronic component, and contact structures according to a first embodiment of the present invention, and FIG. 2 is an enlarged sectional view showing a part of one of the contact structures shown in FIG. 1. FIG. 3 is a partial sectional view showing a substrate, an electronic component, and contact structures according to a second embodiment of the present invention, and FIG. 4 is an enlarged sectional view showing a part of one of the contact structures shown in FIG. 3. FIG. 5 is a partial sectional view showing contact structures according to a third embodiment of the present invention.

With reference to FIG. 1, an electronic component 2 is attached to a substrate 1 made of an insulating material. The electronic component 2 is, for example, an IC, a capacitor, a transistor, etc.

As shown in FIG. 1, terminals 2a made of Al or the like are provided on the bottom surface of the electronic component 2.

The terminals 2a are electrically connected to a wiring pattern (not shown) formed on the substrate 1 by contact structures 3, which will be described below.

As shown in FIG. 1, the contact structures 3 are provided on the substrate 1, the number and positions of the contact structures 3 corresponding to those of the terminals 2a. In the embodiment shown in FIGS. 1 and 2, each of the contact structures 3 includes contact members 5, 6, and 7 and sacrificial layers 8.

As shown in FIG. 1, the contact structures 3 are provided under their respective terminals 2a, and each contact structure 3 has three contact members 5, 6, and 7. For convenience, in each contact structure 3, the lowermost contact member (the contact member nearest to the substrate 1 in FIG. 1) is called a “first contact member 5”, the middle contact member is called a “second contact member 6”, and the uppermost contact member is called a “third contact member 7” in the following description.

As shown in FIG. 1, the contact members 5, 6, and 7 respectively include fixed portions 5a, 6a, and 7a and leg portions 5b, 6b, and 7b extending from the fixed portions 5a, 6a, and 7a in the same direction. The sacrificial layers 8 are interposed between the fixed portions 5a, 6a, and 7a, and the fixed portions 5a, 6a, and 7a are bonded to each other with the sacrificial layers 8 interposed therebetween. The fixed portions 5a, 6a, and 7a correspond to regions in which the contact members 5, 6, and 7 are in contact with the sacrificial layers 8 (that is, regions in which the contact members 5, 6, and 7 are fixed by the sacrificial layers 8), and the leg portions 5b, 6b, and 7b correspond to the other regions.

As shown in FIG. 1, another sacrificial layer 8 is disposed between the fixed portion 5a of the first contact member 5 and the substrate 1, and thus the first contact member 5 is bonded to the substrate 1.

In FIG. 1, all of the leg portions 5b, 6b, and 7b extend from the fixed portions 5a, 6a, and 7a in the same direction (direction parallel to the X1-X2 direction in FIG. 1) in each laminate structure. More specifically, in the contact structure 3 at the left of the substrate 1 in FIG. 1, all of the leg portions 5b, 6b, and 7b extend rightward (in the X1 direction) from the fixed portions 5a, 6a, and 7a, respectively. In addition, in the contact structure 3 at the right of the substrate 1 in FIG. 1, all of the leg portions 5b, 6b, and 7b extend leftward (in the X2 direction) from the fixed portions 5a, 6a, and 7a. However, it is not necessary that all of the leg portions 5b, 6b, and 7b extend in the same direction, and one of the leg portions 5b, 6b, and 7b may also extend in a direction different from the extending direction of the other leg portions. In addition, although each of the contact members 5, 6, and 7 has a single leg portion in this example, two or more leg portions may also be provided for each of the contact members 5, 6, and 7. For example, the leg portions 5b, 6b, and 7b may also be provided at both sides of the fixed portions 5a, 6a, and 7a. More specifically, the leg portions 5b, 6b, and 7b may extend in two directions from the fixed portions 5a, 6a, and 7a.

As shown in FIG. 1, the fixed portions 5a, 6a, and 7a of the contact members 5, 6, and 7 are bonded to the substrate 1 with the sacrificial layers 8 interposed therebetween. However, no sacrificial layers 8 are provided between the leg portions 5b, 6b, and 7b, and the leg portions 5b, 6b, and 7b are free in the vertical direction. As explained in the following description regarding a manufacturing method, different internal stresses are applied between the top and bottom sides of each of the leg portions 5b, 6b, and 7b. Since different internal stresses are applied between the top and bottom sides of each of the leg portions 5b, 6b, and 7b, the leg portions 5b, 6b, and 7b are deflected. In the embodiment shown in FIGS. 1 and 2, all of the leg portions 5b, 6b, and 7b are deflected upward (in the Y1 direction in FIG. 1). In other words, the leg portions 5b, 6b, and 7b are deflected toward the terminals 2a of the above-described electronic component 2.

The leg portions 5b, 6b, and 7b are elastically deflected into a curved shape as shown in FIG. 1 because of the internal stress as described above. As explained in the following description regarding the manufacturing method, different internal stresses are applied between the top and bottom sides of the leg portions 5b, 6b, and 7b in the manufacturing process thereof. More specifically, a tensile stress is applied to the bottom sides of the leg portions 5b, 6b, and 7b, and a compressive stress is applied to the top sides of the leg portions 5b, 6b, and 7b. As a result, the leg portions 5b, 6b, and 7b are deflected upward in the figure.

As shown in FIG. 2, the surfaces of the contact members 5, 6, and 7 are coated with metal layers 9 made of Au or the like. As described below, the metal layers 9 are formed by, for example, plating. Although the metal layers 9 may also be omitted, they are preferably provided to prevent reduction of conductivity due to rust or the like.

As shown in FIGS. 1 and 2, each terminal 2a of the electronic component 2 faces the corresponding contact structure 3 such that the leg portions 5b, 6b, and 7b of the contact members 5, 6, and 7 in the contact structure 3 are in contact with the terminal 2a at ends 5b1, 6b1, and 7b1 thereof. The ends 5b1, 6b1, and 7b1 serve as contacts, and when the electronic component 2 shown in FIG. 1 is placed on (or pushed downward against) the ends 5b1, 6b1, and 7b1, the leg portions 5b, 6b, and 7b of the contact members 5, 6, and 7 elastically deform downward. In the case in which the ends 5b1, 6b1, and 7b1 of the leg portions 5b, 6b, and 7b are at different vertical positions when the electronic component 2 is not yet placed on the ends 5b1, 6b1, and 7b1, one of the leg portions 5b, 6b, and 7b comes into contact with the electronic component 2 first and elastically deforms downward. Then, the other leg portions successively come into contact with the electronic component 2, and thus the ends 5b1, 6b1, and 7b1 of the leg portions 5b, 6b, and 7b easily come into contact with the terminal 2a of the electronic component 2.

In this case, even when the electronic component 2 is displaced in the process of placing it on the substrate 1 and the end 7b1 of the leg portion 7b of the third contact member 7, for example, comes into contact with the electronic component 2 at a position outside the terminal 2a, at least one of the ends 5b1 and 6b1 of the leg portions 5b and 6b of the other contact members 5 and 6 is easily caused to come into contact with the terminal 2a of the electronic component 2.

As described above, according to the present invention, a plurality of contact members 5, 6, and 7 are laminated, and all of the leg portions 5b, 6b, and 7b are deflected upward due to the internal stress. Accordingly, the leg portions 5b, 6b, and 7b, which function as elastic contacts, easily come into contact with the terminals 2a of the electronic component 2. In addition, even when the electronic component 2 is placed on the substrate 1 at a position shifted from a predetermined installation position, at least one of the leg portions 5b, 6b, and 7b of the contact members 5, 6, and 7 easily comes into contact with the corresponding terminal 2a of the electronic component 2. Thus, a good electrical connection is provided between the electronic component 2 and the substrate 1, and reliability of the contacts is increased.

In the process of electrically connecting the electronic component 2 to the substrate 1, if the substrate 1 has an irregular surface, the vertical position of the ends 5b1, 6b1, and 7b1 of the three contact members 5, 6, and 7 in the contact structure 3 on the left in FIG. 1 may differ from that of the ends 5b1, 6b1, and 7b1 of the three contact members 5, 6, and 7 in the contact structure 3 on the right in FIG. 1. Even in such a case, the leg portions 5b, 6b, and 7b of the contact members 5, 6, and 7, which function as elastic contacts, elastically deform due to a load applied when the electronic component 2 is placed, and a plurality of elastic contacts adequately come into contact with the terminals 2a of the electronic component 2.

As shown in FIG. 2, all of the leg portions 5b, 6b, and 7b of the three laminated contact members 5, 6, and 7 are deflected upward. Preferably, the length of the leg portion 7b of the third contact member 7 at the uppermost position is shortest, the length of the leg portion 6b of the second contact member 6 in the middle position is between the lengths of the leg portions 5b and 7b of the first and third contact members 5 and 7, respectively, and the length of the leg portion 5b of the first contact member 5 at the lowermost position is longest.

With reference to FIG. 2, the lengths of the leg portions 5b, 6b, and 7b are defined as dimensions along center lines A-A, B-B, and C-C of the leg portions 5b, 6b, and 7b, the center lines A-A, B-B, and C-C extending along the centers of the contact members 5, 6, and 7 in the thickness direction thereof. More specifically, according to the present invention, (the length of the leg portion 7b along the center line A-A)<(the length of the leg portion 6b along the center line B-B)<(the length of the leg portion 5b along the center line C-C) is preferably satisfied.

Accordingly, the ends 5b1, 6b1, and 7b1 of the upwardly deflected leg portions 5b, 6b, and 7b are easily arranged at the same vertical position. As described above, even if the ends 5b1, 6b1, and 7b1 are not arranged at the same vertical position, the ends 5b1, 6b1, and 7b1 easily come into contact with the terminals 2a of the electronic component 2 since the leg portions 5b, 6b, and 7b deform elastically. However, in order to bring the ends 5b1, 6b1, and 7b1 into contact with the terminals 2a of the electronic component 2 more reliably, the lengths of the leg portions 5b, 6b, and 7b of the first, second, and third contact members 5, 6, and 7 are preferably adjusted as described above.

According to the present invention, the ends 5b1, 6b1, and 7b1 of the contact members 5, 6, and 7 in each contact structure 3 on the substrate 1 are bonded to the corresponding terminal 2a of the electronic component 2 by means of conductive adhesive, soldering, welding, or the like. Alternatively, as shown in FIG. 1, bent-shaped fixing members 12 for fixing the electronic component 2 on the substrate 1 may be provided between the substrate 1 and a top surface 2b of the electronic component 2. Alternatively, an insulating resin layer 13 or the like for fixing the electronic component 2 on the substrate 1 may be provided between the electronic component 2 and the substrate 1 in a region where the contact structures 3 are not provided. In either case, a desired electric test may be performed while the electronic component 2 and the substrate 1 are provisionally connected to each other by the contact structures 3, and the electronic component 2 may be fixed on the substrate 1 with the conductive adhesive or the like after passing the electric test. Since a plurality of contact members 5, 6, and 7 are provided in each contact structure 3 and the leg portions 5b, 6b, and 7b of the contact members 5, 6, and 7 easily come into contact with the corresponding terminal 2a of the electronic component 2, the electric test can be adequately performed.

In addition, since the leg portions 5b, 6b, and 7b have different lengths as shown in FIG. 2, the amount of elastic deformation in the vertical direction (the Y1-Y2 direction in FIG. 1) when a certain pressing force is applied (or the pressing force required for obtaining a certain amount of elastic deformation) differs between the leg portions 5b, 6b, and 7b. In other words, the bending moment differs between the leg portions 5b, 6b, and 7b. If the leg portions 5b, 6b, and 7b are made of the same material and have the same thickness, when they are pressed downward with a certain pressing force, the shortest leg portion 7b causes the smallest amount of elastic deformation in the vertical direction (in other words, the leg portion 7b is most difficult to deform). In addition, the longest leg portion 5b causes the largest amount of elastic deformation in the vertical direction (in other words, the leg portion 5b is most easily deformed). Although the ends 5b1, 6b1, and 7b1 of all of the leg portions 5b, 6b, and 7b are preferably arranged at the same vertical position as described above, it is difficult to arrange all of the ends 5b1, 6b1, and 7b1 at the same vertical position in practice. Accordingly, the leg portions 5b, 6b, and 7b are preferably deflected such that the end 5b1 of the longest leg portion 5b is at the height position. In such a case, the ends 5b1, 6b1, and 7b1 of the leg portions 5b, 6b, and 7b easily come into contact with the corresponding terminal 2a of the electronic component 2.

The sacrificial layers 8 are made of, for example, Ti or a resin in which a conductive filler is mixed. Although the sacrificial layers 8 may also be insulative, they are preferably conductive so that the terminals 2a of the electronic component 2 can be electrically connected to the substrate 1 via the leg portions 5b, 6b, and 7b, the fixed portions 5a, 6a, and 7a, and the sacrificial layers 8, as in the embodiment shown in FIG. 1. When the sacrificial layers 8 are insulative, conductive members for providing electrical connection between the contact members 5, 6, and 7 and the substrate 1 must be additionally provided.

The gap T1 between the terminals 2a of the electronic component 2 is in the range of 20 μm to 500 μm.

As shown in FIG. 2, the leg portions 5b, 6b, and 7b of the contact members 5, 6, and 7 are provided with through holes 5c, 6c, and 7c, respectively. The through holes 5c, 6c, and 7c are used in the manufacturing method described below.

FIGS. 3 and 4 show an example in which an interposer (contact structures and a transmission substrate) 15 is provided between an electronic component 2 and a substrate 1.

The interposer 15 includes contact sections 15a provided under terminals 2a of the electronic component 2, the number and positions of the contact sections 15a corresponding to those of the terminals 2a. Each of the contact sections 15a has a laminate of contact members 16 and 17.

The interposer 15 include a sheet member 18 on which the contact members 16 and 17 are attached. The sheet member 18 is, for example, a resin sheet made of polyimide or the like.

As shown in FIGS. 3 and 4, in each contact section 15a, the contact members 16 and 17 respectively include fixed portions 16a and 17a and leg portions 16b and 17b extending from the fixed portions 16a and 17a in the same direction and having free ends. As shown in FIGS. 3 and 4, a sacrificial layer 8 is provided between the fixed portions 16a and 17a, and the fixed portions 16a and 17a are bonded to each other with the sacrificial layer 8. In addition, as shown in FIGS. 3 and 4, the fixed portion 16a of the contact member 16 adjacent to the sheet member 18 is bonded to the sheet member 18 with another sacrificial layer 8 interposed therebetween. The materials of the contact members 16 and 17 and the sacrificial layers 8 are the same as those described with reference to FIGS. 1 and 2.

The surfaces of the contact members 16 and 17 are coated with metal layers 19. The metal layers 19 are made of Au or the like and are formed by, for example, plating.

As shown in FIGS. 3 and 4, in each contact section 15a, the leg portion 16b extending from the fixed portion 16a of the contact member 16 adjacent to the sheet member 18 (that is, the lower contact member) is deflected downward. As shown in FIGS. 3 and 4, through holes 20 are formed in the sheet member 18 at positions corresponding to the leg portions 16b. Each of the leg portions 16b is deflected so as to extend through the corresponding through hole 20 such that an end 16b1 thereof projects downward from the bottom surface of the sheet member 18 and is electrically connected to a predetermined wiring pattern on the substrate 1. Accordingly, in the embodiment shown in FIGS. 3 and 4, the end 16b1 of each leg portion 16b functions as a contact.

In addition, in each contact section 15a, the leg portion 17b of the contact member 17 distant from the sheet member 18 (that is, the upper contact member) is deflected upward such that an end 17b1 thereof is electrically connected to the corresponding terminal 2a on the electronic component 2. Accordingly, in the embodiment shown in FIGS. 3 and 4, the end 17b1 of each leg portion 17b also functions as a contact.

In the embodiment shown in FIGS. 3 and 4, in each laminate of the contact members 16 and 17, the leg portion 16b of the lower contact member 16 is deflected downward and the leg portion 17b of the upper contact member 17 is deflected upward. Accordingly, good electrical connections are provided between the substrate 1 and the end 16b1 of the leg portion 16b and between the corresponding terminal 2a of the electronic component 2 and the end 17b1 of the leg portion 17b, and accordingly an electrical connection is reliably provided between the electronic component 2 and the substrate 1.

Since the leg portions 16b and 17b of the contact members 16 and 17 are elastically deformable, when the electronic component 2 is placed on the leg portions 17b of the contact members 17, the leg portions 16b and 17b are elastically deformed to provide a reliable electrical connection between the electronic component 2 and the substrate 1. In addition, even when there is a large difference in coefficient of thermal expansion between the electronic component 2 and the substrate 1, strain caused by the difference in coefficient of thermal expansion can be absorbed by the leg portions 16b and 17b of the contact members 16 and 17 having elasticity, and the electronic component 2 and the substrate 1 can be more reliably connected to each other.

In the interposer 15 shown in FIGS. 3 and 4, the leg portions 16b and 17b of the contact members 16 and 17 are not bent by machining, but are deflected in the predetermined directions using the internal stress in the leg portions 16b and 17b. Thus, an interposer with elastic contacts having a simple structure is provided.

The size of the interposer 15 must be reduced in accordance with the size reduction of the electronic component 2. In addition, the elastic contacts must be arranged at accurate positions between the electronic component 2 and the substrate 1. In the present invention, the elastic contacts are easily provided at accurate positions by the manufacturing method described below.

In the present invention, the leg portions 16b and 17b of the contact members 16 and 17 in each contact section 15a of the interposer 15 are bonded to the substrate 1 and the corresponding terminal 2a of the electronic component 2 by means of conductive adhesive, soldering, welding, or the like. Alternatively, as shown in FIG. 1, bent-shaped fixing members 12 for fixing the electronic component 2 on the substrate 1 may be provided between the substrate 1 and a top surface 2b of the electronic component 2. Alternatively, an insulating resin layer 13 or the like for fixing the electronic component 2 on the substrate 1 may be provided between the electronic component 2 and the substrate 1. In either case, a desired electric test may be performed while the electronic component 2 and the substrate 1 are provisionally connected to each other with the interposer 15 interposed therebetween, as shown in FIG. 3, and the leg portions 16b and 17b may be fixed to the substrate 1 and the electronic component 2 with the conductive adhesive or the like after passing the electric test.

The sacrificial layers 8 are preferably made of a conductive material. In such a case, the contact members 16 and 17 are electrically connected to each other with the sacrificial layers 8 interposed therebetween, and conductive paths are provided between the electronic component 2 and the substrate 1 via the contact members 16, the sacrificial layers 8, and the contact members 17.

The contact members 5, 6, 7, 16, and 17 shown in FIGS. 1 to 4 are preferably formed by a thin-film formation process such as sputter deposition, electron beam evaporation, molecular beam epitaxial deposition, chemical vapor deposition, and electroless plating. When the contact members 5, 6, 7, 16, and 17 are formed as thin films, the size, especially thickness, of the contact members 5, 6, 7, 16, and 17 is reduced, and accordingly the size of the connecting structures between the substrate 1 and the electronic component 2 can be adequately reduced.

The contact members 5, 6, 7, 16, and 17 are preferably formed by sputter deposition. As explained below in the description of the manufacturing method, film forming conditions must be controlled such that different internal stresses are applied to the top and bottom surfaces of each of the contact members 5, 6, 7, 16, and 17. Therefore, sputter deposition is preferably used because different internal stresses can be easily applied to the top and bottom surfaces of each of the contact members 5, 6, 7, 16, and 17 by changing a vacuum gas pressure.

In addition, the metal layers 9 and 19 provided on the surfaces of the contact members 5, 6, 7, 16, and 17 are formed by coating noble metal, such as Au, or Ni having high electrical conductivity, and therefore a good electrical connection is provided between the electronic component 2 and the substrate 1 and reduction of conductivity due to rust or the like is prevented. In addition, as shown in FIGS. 1 to 4, the metal layers 9 and 19 also serve as bonding layers for bonding the terminals 2a of the electronic component 2 to the leg portions of the contact members. The terminals 2a of the electronic component 2 may be bonded to the leg portions of the contact members by, for example, ultrasonic welding.

As shown in FIG. 4, the leg portions 16b and 17b of the contact members 16 and 17 are provided with through holes 16c and 17c, respectively. The through holes 16c and 17c are used in the manufacturing method described below.

As described above, according to the present invention, a plurality of contact members are laminated, and leg portions of the contact members having free ends are deflected in predetermined directions using the internal stress. As shown in FIGS. 1 and 2, when the leg portions 5b, 6b, and 7b are deflected upward in the same direction, each terminal 2a of the electronic component 2 faces multiple leg portions 5b, 6b, and 7b, so that the electrical connection between the terminal 2a and the leg portions 5b, 6b, and 7b is easily obtained. In addition, when the size of the electronic component 2 is reduced, the electronic component 2 must be accurately positioned relative to the substrate 1. According to the present invention, a plurality of contact members 5, 6, and 7 are provided, and it is only necessary to electrically connect at least one of the contact members 5, 6, and 7 to the corresponding terminal 2a of the electronic component 2. Therefore, even when the electronic component 2 is displaced, each terminal 2a is easily connected to at least one of the contact members 5, 6, and 7.

As shown in FIGS. 3 and 4, when the contact members 16 and 17 are deflected in opposite vertical directions, they can be used as contact members of the interposer 15 and the electrical connection between the substrate 1 and the electronic component 2 is reliably provided by the contact members 16 and 17 of the interposer 15 which deform elastically. When the size of the electronic component 2 is reduced, the size of the contact members 16 and 17 in the interposer 15 must also be reduced accordingly. According to the present invention, since the leg portions 16b and 17b are deflected in the predetermined directions using the internal stress, the leg portions 16b and 17b can be adequately deflected in the predetermined directions and be easily arranged at predetermined positions with high accuracy.

As a result, the contact structures shown in FIGS. 1 to 4 provide a higher reliability of contact compared to known structures.

Although the number of contact members 5, 6, and 7 included in each laminate structure is three in FIGS. 1 and 2, the number of contact members may also be two, four, or more. In addition, although the number of contact members 16 and 17 included in each laminate structure is two in FIGS. 3 and 4, the number of contact members may also be three or more, as long as at least one of the contact members is deflected in a direction different from that of the other contact members. If the interposer 15 includes at least four contact members consisting of two contact members having downwardly deflected leg portions and other contact members having upwardly deflected leg portions, the terminals 2a of the electronic component 2 and the substrate 1 come into contact with more than one leg portions. Therefore, the electronic component 2 and the substrate 1 can be reliably connected to each other.

FIG. 5 is a partial sectional view showing an interposer 21 according to a third embodiment of the present invention. In this embodiment, different from FIGS. 3 and 4, a lower contact member 22 is not deflected using the internal stress, but a concave portion 22a is formed in the contact member 22 using a recess formed in a base used in a manufacturing process when the contact member 22 is formed on the base by sputtering. A leg portion 23b of an upper contact member 23 is deflected upward by the internal stress, and an end 23b1 of the leg portion 23b of the contact member 23 projects from an sheet member 18 through a through hole 20 formed in the sheet member 18. As shown in FIG. 5, the contact structure may also be such that a plurality of contact members 22 and 23 are laminated and the leg portion of at least one of the contact members 22 and 23 is deflected due to the internal stress.

In FIG. 5, the concave portion 22a of the contact member 22 is electrically connected to the substrate 1, and the leg portion 23b of the contact member 23 is electrically connected to a terminal 2a of an electronic component 2.

Next, a manufacturing method of the contact structures 3 will be described below.

A manufacturing method of each contact structure 3 disposed between the substrate 1 and the electronic component 2 according to the present invention will be described below with reference to FIGS. 6 to 10. Each figure shows a partial sectional view showing the contact structure 3 being manufactured.

In FIG. 6, a resist layer 30 is applied to the substrate 1 and a negative pattern 30a having the shape corresponding to the first contact member 5 is formed in the resist layer 30 by exposure. The resist layer 30 is made of a resist material for lift off. Then, the sacrificial layer 8 is formed in the negative pattern 30a, and the first contact member 5 is formed on the sacrificial layer 8 by sputter deposition. The sacrificial layer 8 is preferably made of a conductive material, such as Ti and a resin in which a conductive filler is mixed. The first contact member 5 is made of NiZr alloy (with 1 at % Ni), MoCr, etc.

In the process of forming the first contact member 5 by sputter deposition, a vacuum gas pressure (Ar gas, for example, is used) is gradually changed so that a tensile stress is applied to the bottom side of the first contact member 5 and a compressive stress is applied to the top side thereof.

Although the sacrificial layer 8 and the first contact member 5 are also formed on the resist layer 30, as shown in FIG. 6, they can be easily removed by immersing the resist layer 30 in an solvent.

In the step shown in FIG. 7, a resist layer 31 is applied to the first contact member 5 and the substrate 1 and a negative pattern 31a having the shape corresponding to the second contact member 6 is formed in the resist layer 31 by exposure. The resist layer 31 is made of a resist material for lift off. Then, the sacrificial layer 8 is formed in the negative pattern 31a, and the second contact member 6 is formed on the sacrificial layer 8 by sputter deposition. The sacrificial layer 8 is preferably made of a conductive material, such as Ti and a resin in which a conductive filler is mixed. The second contact member 6 is made of NiZr alloy (with 1 at % Ni), MoCr, etc.

In the process of forming the second contact member 6 by sputter deposition, a vacuum gas pressure (Ar gas, for example, is used) is gradually changed so that a tensile stress is applied to the bottom side of the second contact member 6 and a compressive stress is applied to the top side thereof.

As shown in FIG. 7, the first contact member 5 is provided with a plurality of through holes 5c. The through holes 5c are formed in the step shown in FIG. 6. Similarly, through holes 6c are preferably formed in the second contact member 6. The through holes 6c can be formed by forming the resist layer 31 at positions where the through holes 6c are to be formed. The width T2 of the portions of the resist layer 31 for forming the through holes 6c is preferably larger than the width T3 of the through holes 5c formed in the first contact member 5. Accordingly, the through holes 5c in the first contact member 5 are reliably filled with the resist layer 31, and the conductive materials of the sacrificial layer 8 and the second contact member 6 are reliably prevented from entering the through holes 5c formed in the first contact member 5 in the step of forming the sacrificial layer 8 and the second contact member 6.

Then, the resist layer 31 for lift off is removed by immersing it in an solvent.

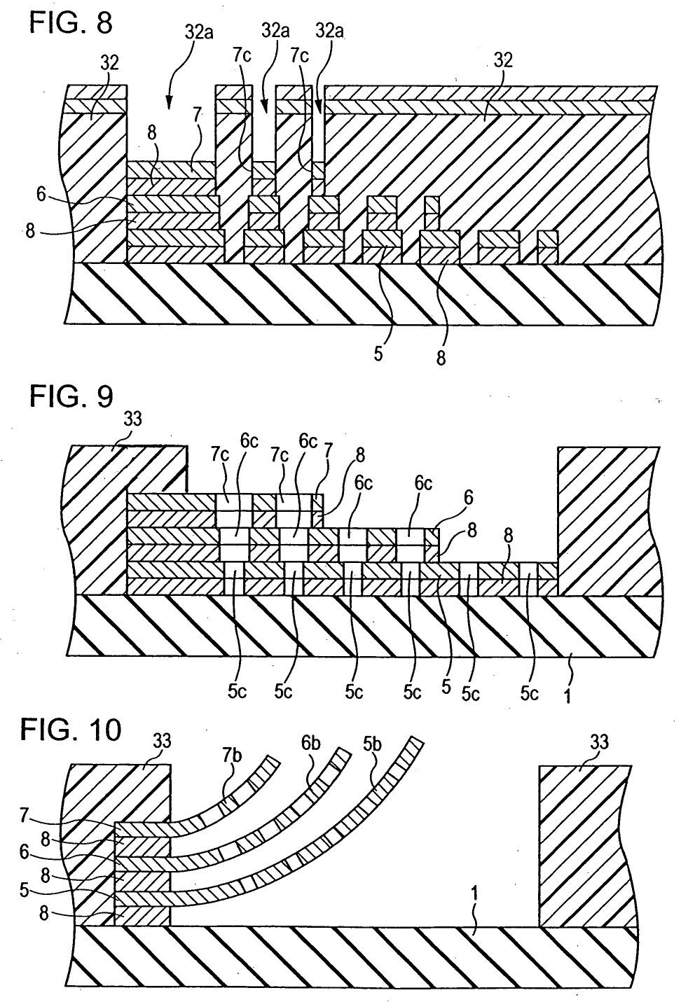

In the step shown in FIG. 8, a resist layer 32 is applied to the first contact member 5, the second contact member 6, and the substrate 1, and a negative pattern 32a having the shape corresponding to the third contact member 7 is formed in the resist layer 32 by exposure. The resist layer 32 is made of a resist material for lift off. Then, the sacrificial layer 8 is formed in the negative pattern 32a, and the third contact member 7 is formed on the sacrificial layer 8 by sputter deposition. The sacrificial layer 8 is preferably made of a conductive material, such as Ti and a resin in which a conductive filler is mixed. The third contact member 7 is made of NiZr alloy (with 1 at % Ni), MoCr, etc.

In the process of forming the third contact member 7 by sputter deposition, a vacuum gas pressure (Ar gas, for example, is used) is gradually changed so that a tensile stress is applied to the bottom side of the third contact member 7 and a compressive stress is applied to the top side thereof.

The through holes 7c are formed in the third contact member 7 by a method similar to that explained with reference to FIG. 7. Then, the resist layer 32 for lift off is removed by immersing it in an solvent.

Next, in the step shown in FIG. 9, a resist layer 33 is formed so as to cover a region corresponding to the fixed portions 5a, 6a, and 7a of the contact members 5, 6, and 7, respectively, peripheral regions along the sides of the fixed portions 5a, 6a, and 7a, and peripheral regions along the sizes of the first contact member 5. Then, the sacrificial layers 8 under the leg portions 5b, 6b, and 7b of the contact members 5, 6, and 7 are removed by wet etching. An etchant used in the wet etching process can selectively remove the sacrificial layers 8, and resolves the sacrificial layers 8 under the leg portions 5b, 6b, and 7b by flowing through the through holes 5c, 6c, and 7c formed in the leg portions 5b, 6b, and 7b of the contact members 5, 6, and 7, respectively.

When the sacrificial layers 8 under the leg portions 5b, 6b, and 7b are removed, the leg portions 5b, 6b, and 7b are released in the vertical direction, and are therefore elastically deformed due to the internal stress (see FIG. 10).

As described above, since a tensile stress is applied to the bottom sides of the contact members 5, 6, and 7 and a compressive stress is applied to the top sides thereof, the leg portions 5b, 6b, and 7b of the contact members 5, 6, and 7 deflect upward. In addition, the fixed portions 5a, 6a, and 7a of the contact members 5, 6, and 7 are continuously fixed on the substrate 1 by the remaining sacrificial layers 8. Next, the resist layer 33 is removed, and the metal layers 9 made of Au or the like are formed on the surfaces of the contact members 5, 6, and 7 by, for example, plating.

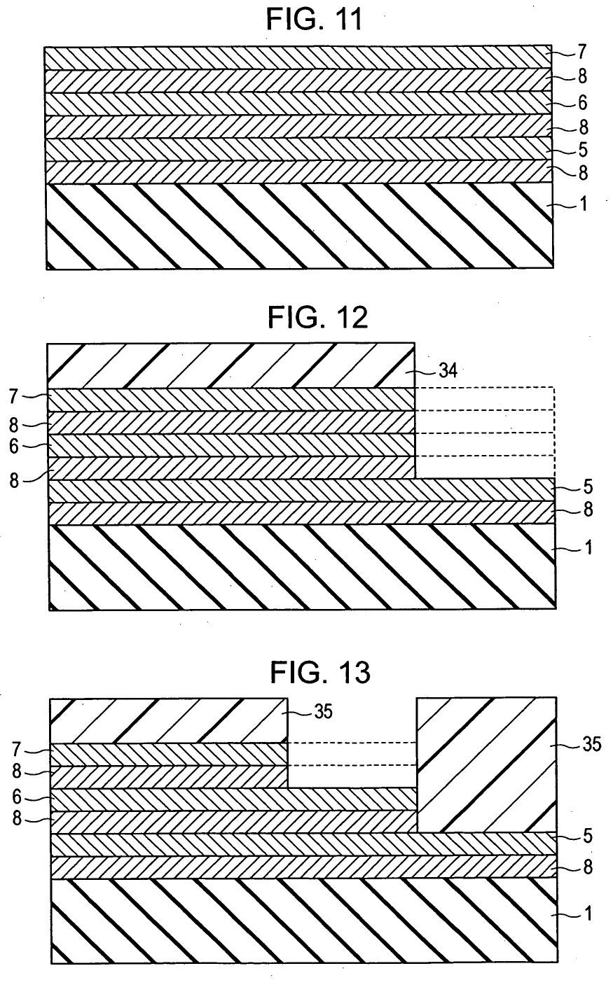

In the steps shown in FIGS. 6 to 10, the lengths of the leg portions 5b, 6b, and 7b of the contact members 5, 6, and 7 are adjusted using the negative patterns of the resist layers 30, 31, and 32 such that the length increases in the order of the leg portion 7b, the leg portion 6b, and the leg portion 5b. However, the contact members 5, 6, and 7 may also be formed by the steps shown in FIGS. 11 to 13.

FIGS. 11 to 13 are partial sectional views showing a second manufacturing method of each contact structure 3 according to the present invention. Each figure shows a partial sectional view showing the contact structure 3 being manufactured.

In FIG. 11, the sacrificial layer 8, the first contact member 5, the sacrificial layer 8, the second contact member 6, the sacrificial layer 8, and the third contact member 7 are successively formed on the substrate 1 over the entire surface thereof. The material of each layer and the manner in which the internal stresses are applied to the contact members are similar to those described above.

First, the contact members 5, 6, and 7 and the sacrificial layers 8 are formed in a pattern corresponding to the shape of the first contact member 5 using a resist layer (not shown). Next, in the step shown in FIG. 12, a resist layer 34 is formed on the third contact member 7. The resist layer 34 is formed in a shape similar to that of the second contact member 6 by exposure. Then, the third contact member 7, the second contact member 6, the sacrificial layer 8 between the third contact member 7 and the second contact member 6, and the sacrificial layer 8 between the second contact member 6 and the first contact member 5 are removed by etching in a region where they are not covered by the resist layer 34. The etching process is stopped when the surface of the first contact member 5 appears. Then, the resist layer 34 is removed by immersing it in an solvent.

Next, in the step shown in FIG. 13, a resist layer 35 is formed on the third contact member 7. The resist layer 35 is formed in a shape similar to that of the third contact member 7 by exposure. In addition, the resist layer 35 is also left in the region where the first contact member 5 is exposed. Then, the third contact member 7 and the sacrificial layer 8 between the third contact member 7 and the second contact member 6 are removed by etching in a region where they are not covered by the resist layer 35. The etching process is stopped when the surface of the second contact member 6 appears. Then, the resist layer 35 is removed by immersing it in an solvent.

Next, the through holes 5c, 6c, and 7c are formed in the contact members 5, 6, and 7 by etching, and the sacrificial layers 8 under the leg portions 5b, 6b, and 7b of the contact members 5, 6, and 7 are removed by wet etching, similar to the step shown in FIG. 9. Accordingly, similar to the step shown in FIG. 10, the leg portions 5b, 6b, and 7b of the contact members 5, 6, and 7 deflect upward.

As shown in FIGS. 11 to 13, the lengths of the leg portions 5b, 6b, and 7b of the contact members 5, 6, and 7 may also be adjusted such that the length increases in the order of the leg portion 7b, the leg portion 6b, and the leg portion 5b by forming the contact members 5, 6, and 7 into predetermined shapes by etching.

The manufacturing method of the contact structures 3 is not limited to those shown in FIGS. 6 to 13.

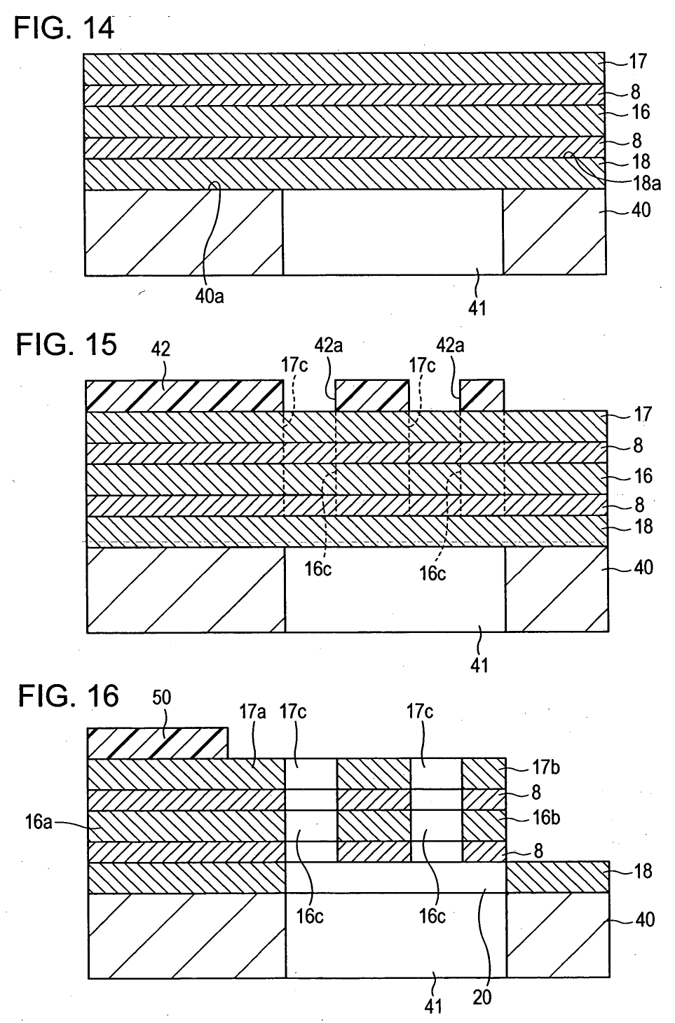

FIGS. 14 to 16 are process charts showing an example of a manufacturing method of the interposer 15 shown in FIGS. 3 and 4. Each figure shows a partial sectional view showing the interposer 15 being manufactured.

In the step shown in FIG. 14, the sheet member 18 is laminated on a surface 40a of a base 40. The base 40 is made of, for example, a copper foil. Through holes 41 are initially formed in the base 40. The through holes 41 are used for forming the through holes 20 shown in FIGS. 3 and 4 in the sheet member 18, and the number and positions of the through holes 41 formed in the base 40 correspond to those of the through holes 20 formed in the sheet member 18.

The sheet member 18 is a resin sheet made of, for example, polyimide.

As shown in FIG. 14, the sacrificial layer 8 is formed on a surface 18a of the sheet member 18 over the entire area thereof. The sacrificial layer 8 is preferably made of a conductive material, such as Ti and a resin in which a conductive filler is mixed.

In the step shown in FIG. 14, the contact member 16 is formed on the sacrificial layer 8 over the entire area thereof by sputter deposition. The contact member 16 is made of NiZr alloy (with 1 at % Ni), MoCr, etc.

In the process of forming the contact member 16 by sputter deposition, a vacuum gas pressure (Ar gas, for example, is used) is gradually changed so that a compressive stress is applied to the bottom side of the contact member 16 and a tensile stress is applied to the top side thereof.

Next, the sacrificial layer 8 is formed on the contact member 16, and then the contact member 17 is formed on the sacrificial layer 8. In the process of forming the contact member 17 by sputter deposition, a vacuum gas pressure (Ar gas, for example, is used) is gradually changed so that a tensile stress is applied to the bottom side of the contact member 17 and a compressive stress is applied to the top side thereof.

In the step shown in FIG. 15, a resist layer 42 is formed on the contact member 17. First, the resist layer 42 is applied to the entire surface of the contact member 17 by spin coating, and is then patterned into the same shape as the contact member 17 by exposure. As shown in FIG. 15, the patterned resist layer 42 has two through holes 42a. The through holes 42a are also formed by exposure.

In the step shown in FIG. 15, the contact members 16 and 17 and the sacrificial layers 8 are removed by etching in a region where they are not covered by the resist layer 42. Ion milling, reactive ion etching, plasma etching, etc., may be used in the etching process. After this etching process, the contact members 16 and 17 having the fixed portions 16a and 17a and the leg portions 16b and 17b are obtained. In addition, in this etching process, the through holes 16c and 17c are formed in the contact members 16 and 17, respectively, by etching through the through holes 42a in the resist layer 42. Similarly, through holes are also formed in the sacrificial layers 8.

Next, the resist layer 42 is removed by immersing it in an solvent.

In the step shown in FIG. 16, the through hole 20 is formed in the sheet member 18 by etching or laser processing through the through hole 41 formed in the base 40. In this etching process, selective etching is performed such that only the sheet member 18 is selectively etched to form the through hole 20. Since the through hole 20 is formed by etching or laser processing as described above, the width of the through hole 20 can be reduced to about ten or more micrometers.

Next, in the step shown in FIG. 16, a resist layer 50 is formed in a region corresponding to the fixed portion 17a the contact member 17 and peripheral regions along the sides of the fixed portions 16a and 7a. Then, the sacrificial layers 8 are removed by, for example, wet etching in a region where it is not covered by the resist layer 50. An etchant used in this wet etching process flows through the through holes 16c and 17c formed in the contact members 16 and 17 and the sacrificial layers 8, and removes the sacrificial layers 8 under the leg portions 16b and 17b of the contact members 16 and 17.

When the sacrificial layers 8 under the leg portions 16b and 17b of the contact members 16 and 17 are removed, the leg portions 16b and 17b are released in the vertical direction, and are therefore deflected because of the internal stress. As described above, since a compressive stress is applied to the bottom side of the leg portion 16b of the lower contact member 16 and a tensile stress is applied to the top side thereof, the leg portion 16b deflects downward. In addition, since a tensile stress is applied to the bottom side of the leg portion 17b of the upper contact member 17 and a compressive stress is applied to the top side thereof, the leg portion 17b deflects upward. At this time, the leg portion 16b of the contact member 16 which is deflected downward extends through the through holes 20 and 41 formed in the sheet member 18 and the base 40, respectively, so that the elastic deformation of the leg portion 16b is not impeded.

Then, the resist layer 50 is removed by immersing it in an solvent. Even when the resist layer 50 is removed, the fixed portions 16a and 17a of the contact members 16 and 17 are continuously fixed on the sheet member 18 by the sacrificial layers 8.

Then, the metal layers 19 made of noble metal, such as Au, or Ni are formed over the entire surfaces of the contact members 16 and 17, and then the base 40 is removed. The base 40 may be removed by, for example, etching. Alternatively, if a removable layer is provided between the base 40 and the sheet member 18 in the step shown in FIG. 14, the base 40 can be easily removed using the removable layer. In such a case, the removed base 40 can be used repeatedly and the manufacturing cost can be reduced accordingly.

In the manufacturing methods shown in FIGS. 6 to 16, the internal stresses in the leg portions of the contact members can also be increased by performing thermal processes. Thus, the contact members can be bent into a curved shape more adequately and easily.

The present invention is characterized in that different internal stresses are applied to the top and bottom sides of the contact members, a plurality of contact members are laminated, and the sacrificial layers 8 under the leg portions of the contact members are removed.

Thus, by performing the above-described steps, the leg portions can be deflected toward predetermined directions using the internal stress. In addition, in the present invention, the fixed portions of the contact members, which are not deflected, are used as bonding areas for bonding the contact members on the substrate 1 or on the sheet member 18.

According to the present invention, the contact members are not bent by machining, but are deflected in the predetermined direction using the internal stress. Therefore, even when the size of the contact members is reduced, the leg portions thereof can be reliably deflected toward the predetermined directions and be used as elastic contacts.

In addition, in a known interposer having a structure in which spring members are provided on the top and bottom sides of a base, it is particularly difficult to place the spring members at predetermined positions on the base. According to the present invention, the contact members 16 and 17 are directly laminated on the sheet member 18, which corresponds to the base, and then it is processed into a predetermined shape by photolithography. Then, the leg portions 16b and 17b of the contact members 16 and 17 are simply deflected in the predetermined directions using the internal stress of the contact members 16 and 17. Accordingly, the contact members 16 and 17 are extremely easily processed, and are easily formed at predetermined positions. In addition, the contact members 16 and 17 can be electrically connected to each other by disposing the sacrificial layer 8 made of a conductive material between the fixed portions 16a and 17a of the contact members 16 and 17.

Although contact structures provided between an electronic component, such as an IC, and a substrate are described above, the contact structures may also be provided between electronic components. The structure of the present invention can be applied to any contact structures provided between electronic members which cover a broad scope including electronic components, substrates, etc.

1. A contact structure comprising a plurality of laminated contact members, each contact member having a fixed portion and a leg portion extending from the fixed portion, wherein the contact members are bonded to each other at the fixed portions and at least one of the leg portions is deflected in a direction perpendicular to a lamination direction of the contact members.

2. The contact structure according to claim 1, wherein sacrificial layers are provided between the fixed portions.

3. The contact structure according to claim 2, wherein the sacrificial layers are made of a conductive material.

4. The contact structure according to claim 3, wherein the contact members are formed by thin-film formation.

5. The contact structure according to claim 4, wherein all of the leg portions are deflected in the same direction.

6. The contact structure according to claim 5, wherein, when all of the leg portions are deflected upward, the leg portions are arranged from the bottom in the order of length, the shortest leg portion being positioned at the top.

7. The contact structure according to one of claim 1 wherein at least one of the leg portions is deflected in a direction different from the direction in which the other leg portions are deflected.

8. The contact structure according to claim 7, further comprising a sheet member to which the fixed portions of the contact members are bonded and which has a through hole, wherein the leg portion of at least one of the contact members is deflected away from the sheet member, and wherein the leg portions of the other contact members are deflected toward the sheet member so as to extend through the through hole and protrude from a surface of the sheet member opposite to a surface on which the fixed portions are bonded.

9. The contact structure according to claim 1, wherein the contact members are formed by thin-film formation.

10. The contact structure according to claim 9, wherein all of the leg portions are deflected in the same direction.

11. The contact structure according to claim 10, wherein, when all of the leg portions are deflected upward, the leg portions are arranged from the bottom in the order of length, the shortest leg portion being positioned at the top.

12. The contact structure according to claim 2, wherein the contact members are formed by thin-film formation.

13. The contact structure according to claim 12, wherein all of the leg portions are deflected in the same direction.

14. The contact structure according to claim 13, wherein, when all of the leg portions are deflected upward, the leg portions are arranged from the bottom in the order of length, the shortest leg portion being positioned at the top.

15. The contact structure according to claim 1, wherein all of the leg portions are deflected in the same direction.

16. The contact structure according to claim 15, wherein, when all of the leg portions are deflected upward, the leg portions are arranged from the bottom in the order of length, the shortest leg portion being positioned at the top.

17. The contact structure according to claim 2, wherein the sacrificial layers are made of a conductive material.

18. The contact structure according to claim 17 wherein all of the leg portions are deflected in the same direction.

19. The contact structure according to claim 2, wherein at least one of the leg portions is deflected in a direction different from the direction in which the other leg portions are deflected.

20. The contact structure according to claim 19, further comprising a sheet member to which the fixed portions of the contact members are bonded and which has a through hole, wherein the leg portion of at least one of the contact members is deflected away from the sheet member, and wherein the leg portions of the other contact members are deflected toward the sheet member so as to extend through the through hole and protrude from a surface of the sheet member opposite to a surface on which the fixed portions are bonded.

21. The contact structure according to claim 2, wherein at least one of the leg portions is deflected in a direction different from the direction in which the other leg portions are deflected.

22. The contact structure according to claim 21, further comprising a sheet member to which the fixed portions of the contact members are bonded and which has a through hole, wherein the leg portion of at least one of the contact members is deflected away from the sheet member, and wherein the leg portions of the other contact members are deflected toward the sheet member so as to extend through the through hole and protrude from a surface of the sheet member opposite to a surface on which the fixed portions are bonded.

23. The contact structure according to claim 3, wherein the contact members are formed by thin-film formation.

24. The contact structure according to claim 23, wherein at least one of the leg portions is deflected in a direction different from the direction in which the other leg portions are deflected.

25. The contact structure according to claim 24, further comprising a sheet member to which the fixed portions of the contact members are bonded and which has a through hole, wherein the leg portion of at least one of the contact members is deflected away from the sheet member, and wherein the leg portions of the other contact members are deflected toward the sheet member so as to extend through the through hole and protrude from a surface of the sheet member opposite to a surface on which the fixed portions are bonded.

26. The contact structure according to claim 1, wherein the contact members are formed by thin-film formation.

27. The contact structure according to claim 26, wherein at least one of the leg portions is deflected in a direction different from the direction in which the other leg portions are deflected.

28. The contact structure according to claim 27, further comprising a sheet member to which the fixed portions of the contact members are bonded and which has a through hole, wherein the leg portion of at least one of the contact members is deflected away from the sheet member, and wherein the leg portions of the other contact members are deflected toward the sheet member so as to extend through the through hole and protrude from a surface of the sheet member opposite to a surface on which the fixed portions are bonded.

29. The contact structure according to claim 2, wherein the contact members are formed by thin-film formation.

30. The contact structure according to claim 29, wherein at least one of the leg portions is deflected in a direction different from the direction in which the other leg portions are deflected.

31. The contact structure according to claim 30, further comprising a sheet member to which the fixed portions of the contact members are bonded and which has a through hole, wherein the leg portion of at least one of the contact members is deflected away from the sheet member, and wherein the leg portions of the other contact members are deflected toward the sheet member so as to extend through the through hole and protrude from a surface of the sheet member opposite to a surface on which the fixed portions are bonded.

32-36. (canceled)
